(19) United States
(12) Patent Application Publication
(10) Pub. No.: US 2023/0257578 A1
(43) Pub. Date: Aug. 17, 2023

(54) RESIN COMPOSITION, PREPREG, FILM PROVIDED WITH RESIN, METAL FOIL PROVIDED WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Mikio SATO, Fukushima (JP); Yuki KITAI, Osaka (JP); Yasunori HOSHINO, Hyogo (JP)

(73) Assignee: PANASONIC INTELLECTUAL PROPERTY MANAGEMENT CO., LTD., Osaka (JP)

(21) Appl. No.: 18/015,864

(22) PCT Filed: Jul. 13, 2021
(86) PCT No.: PCT/JP2021/026273

§ 371 Date: Jan. 12, 2023

(30) Foreign Application Priority Data
Jul. 17, 2020 (JP) 2020-122560

(51) Int. Cl. C08L 71/12; C08K 3/38; C08J 5/24; H05K 1/03

(52) U.S. Cl. CPC C08L 71/123; C08K 3/38; C08J 5/244; H05K 1/0366; C08K 2003/385; C08J 2371/12; C08J 2453/02

(57) ABSTRACT

A resin composition includes: a polyphenylene ether compound; a curing agent reactable with the polyphenylene ether compound; and an inorganic filler including a boron nitride filler, wherein a particle size distribution of the inorganic filler, which is measured by a laser diffraction-based particle size distribution measuring method, has at least two peaks in a particle diameter range of 0.8 to 30.0 μm, the peaks including at least one peak in a particle diameter range of 0.8 to 5.0 μm and at least one peak in a particle diameter range of 5.0 to 30.0 μm.

### TECHNICAL FIELD

The present invention relates to a resin composition, a prepreg, a film with a resin, a metal foil with a resin, a metal-clad laminate, and a wiring board.

### BACKGROUND ART

Various electronic devices have experienced a development in a mounting technique, such as high integration of semiconductor devices to be mounted, high densification of wiring, and multilayer formation, with an increase in the amount of information processing. Besides, wiring boards for use in the various electronic devices are required to adapt to a high-frequency, like a millimeter-wave radar substrate for on-vehicle applications, for example. A reduction of a loss in a signal transmission is required for a wiring board for use in the various electronic devices to increase a transmission rate of a signal, and this is particularly required for a wiring board adapted to a high-frequency. In order to meet this requirement, a raw base material constituting a base material of a wiring board for use in the various electronic devices needs to have a low dielectric constant and a low dielectric loss tangent.

As an example of the raw base material, a PPE (polyphenylene ether)-containing resin composition which contains the PPE, a crosslinking curable compound, and a phosphaphenanthrene derivative has been reported (Patent Literature 1).

On the other hand, a high thermal conductivity, as well as a low dielectric constant and a low dielectric loss tangent, is required for an electronic material for use in a substrate of PA (a power amplifier) in a base station, for example. So far, as a way of enhancing the thermal conductivity in a resin composition, a resin composition for a derivative containing isotropic magnesium oxide was already reported (Patent Literature 2). Further, techniques using boron nitride as an inorganic filler to obtain a still higher thermal conductivity was reported (Patent Literatures 3 and 4).

Indeed, the boron nitride fillers disclosed in Patent Literatures 3 and 4 enhance the thermal conductivity in the resin composition, but involve a problem that an increase in the amount of boron nitride to be added inevitably causes a decrease in the peel strength of the resin composition. Therefore, an increase in the amount of boron nitride to be added alone hardly enables a concurrent attainment of a high thermal conductivity and a high peel strength.

### CITATION LIST

### Patent Literature

Patent Literature 1: JP 2015-67700A

Patent Literature 2: JP 2015-168731A

Patent Literature 3: JP 2013-241321A

Patent Literature 4: JP 2014-208818A

### SUMMARY OF INVENTION

The present invention is made in view of the circumstances described above, and the object thereof is to provide a resin composition from which a cured product having low dielectric characteristics, a high thermal conductivity, and an excellent peel strength is obtainable. Another object of the present invention is to provide a prepreg, a film with a resin, a metal foil with a resin, a metal-clad laminate, and a wiring board which can be obtained by use of the resin composition.

As a result of various studies, the present inventors have found that the object described above would be attainable by a configuration described hereinafter, and have further studied to thereby achieve the present invention.

Specifically, a resin composition according to an aspect of the present invention includes: a polyphenylene ether compound; a curing agent reactable with the polyphenylene ether compound; and an inorganic filler including a boron nitride filler, wherein a particle size distribution of the inorganic filler which is on a measurement of a laser diffraction-based particle size distribution measuring method has at least two peaks in a particle diameter range of 0.8 to 30.0 μm, the peaks including at least one peak in a particle diameter range of 0.8 to 5.0 μm and at least one peak in a particle diameter range of 5.0 to 30.0 μm.

### BRIEF DESCRIPTION OF DRAWINGS

FIG. 1 is a schematic cross-sectional view showing an example of a prepreg according to an embodiment of the present invention.

FIG. 2 is a schematic cross-sectional view showing an example of a metal-clad laminate according to an embodiment of the present invention.

FIG. 3 is a schematic cross-sectional view showing an example of a wiring board according to an embodiment of the present invention.

FIG. 4 is a schematic cross-sectional view showing an example of a metal foil with a resin according to an embodiment of the present invention.

FIG. 5 is a schematic cross-sectional view showing an example of a film with a resin according to an embodiment of the present invention.

### DESCRIPTION OF EMBODIMENTS

The embodiments of the present invention will be specifically described below, but the present invention is not limited thereto.

Resin Composition

A resin composition according to an embodiment of the present invention includes a polyphenylene ether compound, a curing agent reactable with the polyphenylene ether compound, and an inorganic filler including a boron nitride filler, wherein a particle size distribution of the inorganic filler, which is measured by a laser diffraction-based particle size distribution measuring method, has at least two peaks in a particle diameter range of 0.8 to 30.0 μm, the peaks including at least one peak in a particle diameter range of 0.8 to 5.0 μm and at least one peak in a particle diameter range of 5.0 to 30.0 μm.

The configuration makes it possible to provide a resin composition from which a cured product having low dielectric characteristics, a high thermal conductivity, and a high peel strength is obtainable. Further, the resin composition can be used to provide a prepreg, a film with a resin, a metal foil with a resin, a metal-clad laminate, and a wiring board exhibiting an excellent performance.

First, each component of a resin composition according to the present embodiment will be described.

Polyphenylene Ether Compound The polyphenylene ether compound according to the present embodiment is not particularly limited, but a modified polyphenylene ether compound is preferable in terms of the attainment of still lower dielectric characteristics. A polyphenylene ether compound having a group expressed by the formulas (1) or (2) described below is more preferable. The low dielectric characteristics and the high heat resistance of a cured product obtainable from the resin composition are considered to be attributable to the polyphenylene ether compound contained in the resin composition.

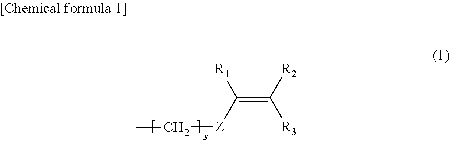

In formula (1), s denotes an integer of 0 to 10. Z represents an arylene group. R₁ to R₃ are independent of one another. In other words, R₁ to R₃ may be the same group or different groups from one another. R₁ to R₃ represent a hydrogen atom or an alkyl group.

When s denotes 0 in formula (1), this means that Z is directly bonded to a terminal end of the polyphenylene ether.

The arylene group of Z is not particularly limited. Examples of this arylene group include a monocyclic aromatic group such as a phenylene group and a polycyclic aromatic group in which the aromatic is not monocyclic but polycyclic aromatic such as a naphthalene ring. The arylene group also includes a derivative in which the hydrogen atom bonded to the aromatic ring is substituted with a functional group such as an alkenyl group, an alkynyl group, a formyl group, an alkylcarbonyl group, an alkenyl carbonyl group, or an alkynyl carbonyl group. The alkyl group is not particularly limited, and for example, an alkyl group having 1 to 18 carbon atoms is preferable, and an alkyl group having 1 to 10 carbon atoms is more preferable. Specific examples thereof include a methyl group, an ethyl group, a propyl group, a hexyl group, and a decyl group.

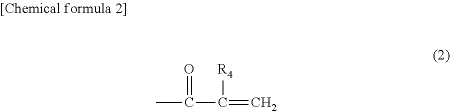

In formula (2), R₄ represents a hydrogen atom or an alkyl group. The alkyl group is not particularly limited, and for example, an alkyl group having 1 to 18 carbon atoms is preferable, and an alkyl group having 1 to 10 carbon atoms is more preferable. Specific examples thereof include a methyl group, an ethyl group, a propyl group, a hexyl group, and a decyl group.

Preferable specific examples of the substituent expressed by the formula (1) include, for example, a substituent containing a vinylbenzyl group. Examples of the substituent containing the vinylbenzyl group include a substituent expressed by the following formula (6). Examples of the substituent expressed by the formula (2) include an acrylate group and a methacrylate group.

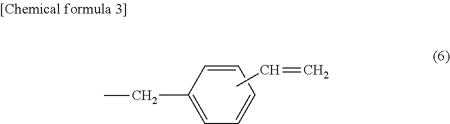

Specific examples of the substituent include a vinylbenzyl group (ethenylbenzyl group) such as p-ethenylbenzyl group and m-ethenylbenzyl group, a vinylphenyl group, an acrylate group, and a methacrylate group.

The polyphenylene ether compound has a polyphenylene ether chain in the molecule and preferably has, for example, a repeating unit expressed by the following formula (7) in the molecule.

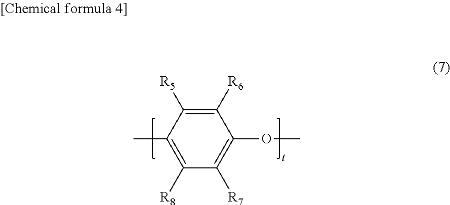

In formula (7), t denotes 1 to 50. R₅ to R₈ are independent of one another. In other words, R₅ to R₈ may be the same group or different groups from one another. R₅ to R₈ represent a hydrogen atom, an alkyl group, an alkenyl group, an alkynyl group, a formyl group, an alkylcarbonyl group, an alkenyl carbonyl group, or an alkynyl carbonyl group. Among these, a hydrogen atom and an alkyl group are preferable.

Specific examples of the respective functional groups mentioned in R₅ to R₈ are listed below.

The alkyl group is not particularly limited and is, for example, preferably an alkyl group having 1 to 18 carbon atoms, and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms, and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms, and more preferably an alkynyl group having 2 to 10 carbon atoms. Specific examples thereof include an ethynyl group and a prop-2-yn-1-yl group (propargyl group).

The alkylcarbonyl group is not particularly limited as long as the alkylcarbonyl group is a carbonyl group substituted with an alkyl group and is, for example, preferably an alkylcarbonyl group having 2 to 18 carbon atoms, and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenyl carbonyl group is not particularly limited as long as the alkenyl carbonyl group is a carbonyl group substituted with an alkenyl group and is, for example, preferably an alkenyl carbonyl group having 3 to 18 carbon atoms, and more preferably an alkenyl carbonyl group having 3 to 10 carbon atoms. Specific examples thereof include an acryloyl group, a methacryloyl group, and a crotonoyl group.

The alkynyl carbonyl group is not particularly limited as long as the alkynyl carbonyl group is a carbonyl group substituted with an alkynyl group and is, for example, preferably an alkynyl carbonyl group having 3 to 18 carbon atoms, and more preferably an alkynyl carbonyl group having 3 to 10 carbon atoms. Specific examples thereof include a propioloyl group.

The weight average molecular weight (Mw) and the number average molecular weight (Mn) of the polyphenylene ether compound are not particularly limited. Specifically, these are preferably 500 to 5,000, more preferably 800 to 4,000, and still more preferably 1,000 to 3,000. The weight average molecular weight and the number average molecular weight here may be measured by a general molecular weight measurement method, and specific examples thereof include a value measured by gel permeation chromatography (GPC). In a case where the polyphenylene ether compound has a repeating unit expressed by formula (11) in the molecule, t preferably denotes a numerical value so that the weight average molecular weight and the number average molecular weight of the polyphenylene ether compound fall within such a range. Specifically, t preferably denotes 1 to 50.

When the molecular weights of the polyphenylene ether compound are within such a range, the polyphenylene ether compound exhibits the excellent low dielectric characteristics of polyphenylene ether and not only imparts superior heat resistance to the cured product but also exhibits excellent moldability. This is considered to be attributed to the following reason. When the weight average molecular weight and the number average molecular weight of ordinary polyphenylene ether are within such a range, the heat resistance of the cured product tends to decrease since the molecular weights are relatively low. With regard to this point, it is considered that a cured product exhibiting sufficiently high heat resistance is obtained since the polyphenylene ether compound according to the present embodiment has more than one unsaturated double bond at the terminal end. When the molecular weights of the polyphenylene ether compound are within such a range, the polyphenylene ether compound has a relatively low molecular weight and is considered to be excellent in moldability as well. Hence, it is considered that such a polyphenylene ether compound is not only excellent in heat resistance of the cured product but also excellent in moldability.

In the polyphenylene ether compound, the average number of the substituents (number of terminal functional groups) at the terminal end of the molecule per one molecule of polyphenylene ether is not particularly limited. Specifically, the number is preferably 1 to 5, more preferably 1 to 3, and still more preferably 1.5 to 3. When this number of functional groups is too small, sufficient heat resistance of the cured product tends to be hardly attained. When the number of terminal functional groups is too large, the reactivity is too high and, for example, there is a possibility that troubles such as a decrease in storage stability of the resin composition and a decrease in fluidity of the resin composition may occur. In other words, when such polyphenylene ether compound is used, for example, there is a possibility that molding defects such as voids generated at the time of multilayer molding may occur by insufficient fluidity and the like and this may cause a moldability problem so that it is difficult to obtain a highly reliable printed wiring board.

The number of terminal functional groups in the polyphenylene ether compound includes a numerical value expressing the average value of the substituents per one molecule of all the modified polyphenylene ether compounds existing in 1 mole of the polyphenylene ether compound. This number of terminal functional groups can be determined, for example, by measuring the number of hydroxyl groups remaining in the obtained modified polyphenylene ether compound and calculating the number of hydroxyl groups decreased from the number of hydroxyl groups in the polyphenylene ether before being modified. The number of hydroxyl groups decreased from the number of hydroxyl groups in the polyphenylene ether before being modified is the number of terminal functional groups. With regard to the method for measuring the number of hydroxyl groups remaining in the modified polyphenylene ether compound, the number of hydroxyl groups can be determined by adding a quaternary ammonium salt (tetraethylammonium hydroxide) to be associated with a hydroxyl group to a solution of the modified polyphenylene ether compound and measuring the UV absorbance of the mixed solution.

The intrinsic viscosity of the polyphenylene ether compound according to the present embodiment is not particularly limited. Specifically, the intrinsic viscosity may be 0.03 to 0.12 dl/g, but preferably 0.04 to 0.11 dl/g, and more preferably 0.06 to 0.095 dl/g. When the intrinsic viscosity is too low, the molecular weight tends to be low and low dielectric characteristics such as a low dielectric constant and a low dielectric loss tangent tend to be hardly attained. When the intrinsic viscosity is too high, the viscosity is high, sufficient fluidity is not attained, and the moldability of the cured product tends to decrease. Hence, if the intrinsic viscosity of the polyphenylene ether compound is within the above range, excellent heat resistance and moldability of the cured product can be realized.

The intrinsic viscosity here is an intrinsic viscosity measured in methylene chloride at 25° C. and more specifically is, for example, a value acquired by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound according to the present embodiment include a modified polyphenylene ether compound expressed by the following formula (8) and a modified polyphenylene ether compound expressed by the following formula (9). As the polyphenylene ether compound according to the present embodiment, these modified polyphenylene ether compounds may be used singly or two kinds of these modified polyphenylene ether compounds may be used in combination.

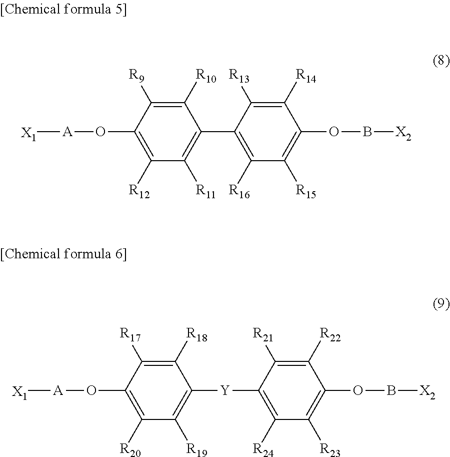

In the formulas (8) and (9), R₉ to R₁₆ and R₁₇ to R₂₄ each independently represents a hydrogen atom, an alkyl group, an alkenyl group, an alkynyl group, a formyl group, an alkylcarbonyl group, an alkenyl carbonyl group, or an alkynyl carbonyl group. X₁ and X₂ each independently represents a substituent having a carbon-carbon unsaturated double bond. A and B respectively represent repeating units expressed by the following formulas (10) and (11). In the formula (9), Y represents a linear, branched, or cyclic hydrocarbon having 20 or less carbon atoms.

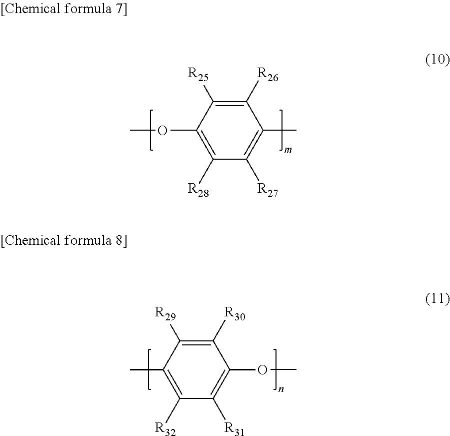

In the formulas (10) and (11), m and n each denotes 0 to 20. R₂₅ to R₂₈ and R₂₉ to R₃₂ each independently represents a hydrogen atom, an alkyl group, an alkenyl group, an alkynyl group, a formyl group, an alkylcarbonyl group, an alkenyl carbonyl group, or an alkynyl carbonyl group.

The modified polyphenylene ether compound expressed by the formula (8) and the modified polyphenylene ether compound expressed by the formula (9) are not particularly limited as long as they are compounds satisfying the above configuration. Specifically, in the formulas (8) and (9), R₉ to R₁₆ and R₁₇ to R₂₄ are independent of one another as described above. In other words, R₉ to Rib and R₁₇ to R₂₄ may be the same group or different groups from one another. R₉ to R₁₆ and Rig to R₂₄ represent a hydrogen atom, an alkyl group, an alkenyl group, an alkynyl group, a formyl group, an alkylcarbonyl group, an alkenyl carbonyl group, or an alkynyl carbonyl group. Among these, a hydrogen atom and an alkyl group are preferable.

In the formulas (10) and (11), m and n each preferably denotes 0 to 20 as described above. It is preferable that m and n denote numerical values so that the sum of m and n is 1 to 30. Hence, it is more preferable that m denotes 0 to 20, n denotes 0 to 20, and the sum of m and n is 1 to 30. R₂₅ to R₂₈ and R₂₉ to R₃₂ are independent of one another. In other words, R₂₅ to R₂₈ and R₂₉ to R₃₂ may be the same group or different groups from one another. R₂₅ to R₂₈ and R₂₉ to R₃₂ represent a hydrogen atom, an alkyl group, an alkenyl group, an alkynyl group, a formyl group, an alkylcarbonyl group, an alkenyl carbonyl group, or an alkynyl carbonyl group. Among these, a hydrogen atom and an alkyl group are preferable.

R₉ to R₃₂ are the same as R₅ to R₈ in the formula (7).

In the formula (9), Y represents a linear, branched, or cyclic hydrocarbon having 20 or less carbon atoms as described above. Examples of Y include a group expressed by the following formula (12).

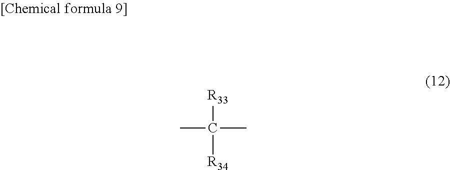

In the formula (12), R₃₃ and R₃₄ each independently represents a hydrogen atom or an alkyl group. Examples of the alkyl group include a methyl group. Examples of the group expressed by the formula (12) include a methylene group, a methylmethylene group, and a dimethylmethylene group. Among these, a dimethylmethylene group is preferable.

In the formulas (8) and (9), X₁ and X₂ are each an independent substituent having a carbon-carbon unsaturated double bond. The substituents X₁ and X₂ are not particularly limited as long as the substituents X₁ and X₂ have a carbon-carbon unsaturated double bond. Examples of the substituents X₁ and X₂ include a substituent expressed by the following formula (1) and a substituent expressed by the following formula (2). In the modified polyphenylene ether compound expressed by the formula (8) and the modified polyphenylene ether compound expressed by the formula (9), X₁ and X₂ may be the same substituent or different substituents from each other.

More specific examples of the modified polyphenylene ether compound expressed by the formula (8) include a modified polyphenylene ether compound expressed by the following formula (13).

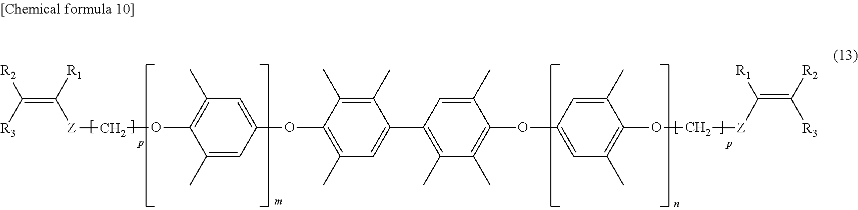

More specific examples of the modified polyphenylene ether compound expressed by the formula (9) include a modified polyphenylene ether compound expressed by the following formula (14) and a modified polyphenylene ether compound expressed by the following formula (15).

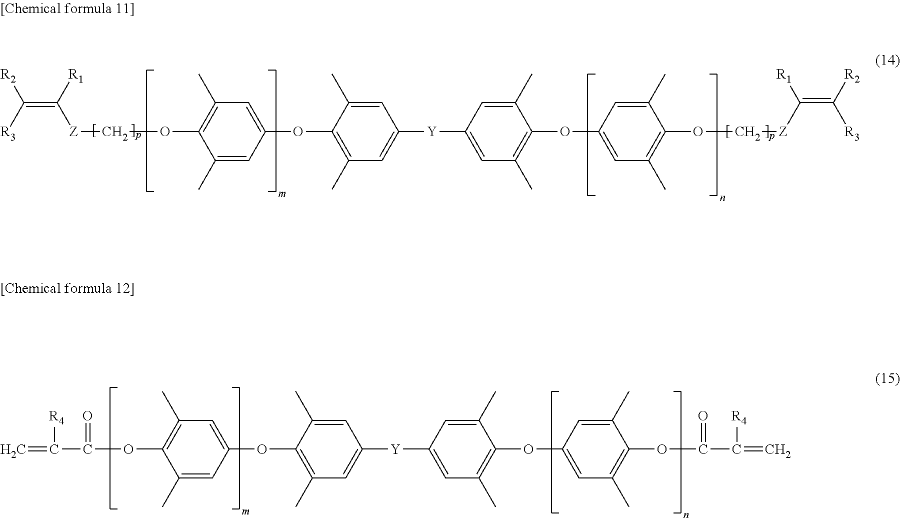

In the formulas (13) to (15), m and n are the same as m and n in the formulas (10) and (11). In the formulas (13) and (14), R₁ to R₃, p, and Z are the same as R₁ to R₃, s, and Z in the formula (1). In the formulas (14) and (15), Y is the same as Y in the above (9). In the formula (14), R₄ is the same as R₄ in the formula (2).

The method for synthesizing the polyphenylene ether compound used in the present embodiment is not particularly limited as long as a polyphenylene ether compound of which the terminal end is modified with a group expressed by the formula (1) and/or the formula (2) can be synthesized. Specific examples thereof include a method in which polyphenylene ether is reacted with a compound in which a substituent having a carbon-carbon unsaturated double bond is bonded to a halogen atom.

Examples of the compound in which a substituent having a carbon-carbon unsaturated double bond is bonded to a halogen atom include compounds in which substituents expressed by the formulas (1), (2), and (6) are bonded to a halogen atom. Specific examples of the halogen atom include a chlorine atom, a bromine atom, an iodine atom, and a fluorine atom. Among these, a chlorine atom is preferable. More specific examples of the compound in which a substituent having a carbon-carbon unsaturated double bond is bonded to a halogen atom include p-chloromethylstyrene and m-chloromethylstyrene.

Polyphenylene ether which is a raw material is not particularly limited as long as a predetermined modified polyphenylene ether compound can be finally synthesized. Specific examples thereof include those containing polyphenylene ether composed of 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the polyphenylene ether compound according to the present embodiment include the methods described above. Specifically, polyphenylene ether as described above and a compound in which a substituent having a carbon-carbon unsaturated double bond is bonded to a halogen atom are dissolved in a solvent and stirred. This causes the polyphenylene ether to react with the compound in which a substituent having a carbon-carbon unsaturated double bond is bonded to a halogen atom, and the polyphenylene ether compound used in the present embodiment is obtained.

The reaction is preferably conducted in the presence of an alkali metal hydroxide. The reaction is considered to proceed suitably in this way. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and consequently, the substituent having a carbon-carbon unsaturated double bond is bonded to the oxygen atom of the phenol group instead of the hydrogen atom of the phenol group in the polyphenylene ether.

The alkali metal hydroxide is not particularly limited as long as the alkali metal hydroxide can act as a dehalogenating agent, and examples thereof include sodium hydroxide. The alkali metal hydroxide is usually used in the form of an aqueous solution and is specifically used as an aqueous sodium hydroxide solution.

The reaction conditions such as reaction time and reaction temperature also vary depending on the compound in which a substituent having a carbon-carbon unsaturated double bond is bonded to a halogen atom and the like, and are not particularly limited as long as they are conditions under which the reaction as described above suitably proceeds. Specifically, the reaction temperature is preferably room temperature to 100° C., more preferably 30° C. to 100° C. The reaction time is preferably 0.5 to 20 hours, more preferably 0.5 to 10 hours.

The solvent used at the time of the reaction is not particularly limited as long as the solvent can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples thereof include toluene.

The above reaction is preferably conducted in the presence of not only an alkali metal hydroxide but also a phase transfer catalyst. In other words, the above reaction is preferably conducted in the presence of an alkali metal hydroxide and a phase transfer catalyst. The above reaction is considered to proceed suitably in this way. This is considered to be attributed to the following reason. This is considered to be because the phase transfer catalyst is a catalyst which has a function of taking in the alkali metal hydroxide, is soluble in both of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is incompatible with water is used as a solvent, it is considered that even when the aqueous sodium hydroxide solution is dropped into the solvent subjected to the reaction, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, when the reaction is conducted in the presence of an alkali metal hydroxide and a phase transfer catalyst, it is considered that the above reaction more suitably proceeds.

The phase transfer catalyst is not particularly limited, and examples thereof include quaternary ammonium salts such as tetra-n-butylammonium bromide.

The resin composition used in the present embodiment preferably contains a modified polyphenylene ether compound obtained as described above as the polyphenylene ether compound.

Curing Agent

The resin composition according to the present embodiment further contains a curing agent reactable with the polyphenylene ether compound;

The curing agent is not particularly limited as long as the curing agent can react with the polyphenylene ether compound and cure the resin composition containing the polyphenylene ether compound. Examples of the curing agent include a curing agent having at least one functional group which contributes to the reaction with the polyphenylene ether compound in the molecule.

Specific examples thereof include a compound having two or more unsaturated double bonds in the molecule. More specifically, examples thereof include styrene derivatives, a compound having an acryloyl group in the molecule, and a compound having a methacryloyl group in the molecule, a compound having a vinyl group in the molecule, a compound having an allyl group in the molecule, a compound having a maleimide group in the molecule, a compound having an acenaphthylene structure in the molecule, and an isocyanurate compound having an isocyanurate group in the molecule.

Examples of the styrene derivatives include bromostyrene and dibromostyrene.

The compound having an acryloyl group in the molecule is an acrylate compound. Examples of the acrylate compound include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include tricyclodecanedimethanol diacrylate.

A compound having a methacryloyl group in the molecule is a methacrylate compound.

Examples of the methacrylate compound include a monofunctional methacrylate compound having one methacryloyl group in the molecule, and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include tricyclodecane dimethanol dimethacrylate.

The compound having a vinyl group in the molecule is a vinyl compound. Examples of the vinyl compound include a monofunctional vinyl compound (monovinyl compound) having one vinyl group in the molecule and a polyfunctional vinyl compound having two or more vinyl groups in the molecule. Examples of the polyfunctional vinyl compound include divinylbenzene and polybutadiene.

The compound having an allyl group in the molecule is an allyl compound. Examples of the allyl compound include a monofunctional allyl compound having one allyl group in the molecule and a polyfunctional allyl compound having two or more allyl groups in the molecule. Examples of the polyfunctional allyl compound include diallyl phthalate (DAP).

The compound having a maleimide group in the molecule is a maleimide compound. Examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

A compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkylacenaphthylenes include 1-methylacenaphthylene, 3-methylacenaphthylene, 4-methylacenaphthylene, 5-methylacenaphthylene, 1-ethylacenaphthylene, 3-ethylacenaphthylene, 4-ethylacenaphthylene, and 5-ethylacenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be the aforementioned monofunctional acenaphthylene compound having one acenaphthylene structure in the molecule, or a polyfunctional acenaphthylene compound having two or more acenaphthylene structures in the molecule.

A compound having an isocyanurate group in the molecule is an isocyanurate compound. The isocyanurate compound may be a compound further containing an alkenyl group in the molecule (alkenyl isocyanurate compound), and examples thereof include a trialkenyl isocyanurate compound such as triallyl isocyanurate (TAIC).

Among these, preferable examples of the curing agent used in the present embodiment include a polyfunctional acrylate compound having two or more acryloyl groups in the molecule, a polyfunctional methacrylate compound having two or more methacryloyl groups in the molecule, a polyfunctional vinyl compound having two or more vinyl groups in the molecule, a styrene derivative, an allyl compound having an allyl group in the molecule, a maleimide compound having a maleimide group in the molecule, an acenaphthylene compound having an acenaphthylene structure in the molecule, and an isocyanurate compound having an isocyanurate group in the molecule.

The curing agents may be used singly or in combination of two or more kinds thereof.

The curing agent preferably has a weight average molecular weight of 100 to 5,000, more preferably 100 to 4,000, and still more preferably 100 to 3,000. When the weight average molecular weight of the curing agent is too low, the curing agent may easily volatilize from the compounding component system of the resin composition. When the weight average molecular weight of the curing agent is too high, the viscosity of the varnish of the resin composition and the melt viscosity at the time of heat molding may be too high. Hence, a resin composition imparting superior heat resistance to the cured product is obtained when the weight average molecular weight of the curing agent is within such a range. This is considered to be because the resin composition containing the polyphenylene ether compound can be suitably cured by a reaction with the polyphenylene ether compound. The weight average molecular weight here may be measured by a general molecular weight measurement method, and specific examples thereof include a value measured by gel permeation chromatography (GPC).

The average number (number of functional groups) of the functional groups which contribute to the reaction of the curing agent with the polyphenylene ether compound per one molecule of the curing agent varies depending on the weight average molecular weight of the curing agent but is, for example, preferably 1 to 20, and more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

Inorganic Filler The resin composition according to the present embodiment further includes an inorganic filler containing boron nitride. The boron nitride is not particularly limited as long as the boron nitride can be used as an inorganic filler to be included in the resin composition and meets the requirements for the particle size distribution described below. Examples of the boron nitride include a hexagonal boron nitride in a normal pressure phase (h-BN) and a cubic boron nitride in a high pressure phase (c-BN).

In the inorganic filler according to the present embodiment, a particle size distribution of the inorganic filler, which is measured by a laser diffraction-based particle size distribution measuring method, has at least two peaks in a particle diameter range of 0.8 to 30.0 μm, the peaks including at least one peak in a particle diameter range of 0.8 to 5.0 μm and at least one peak in a particle diameter range of 5.0 to 30.0 μm. Specifically, in the inorganic filler used in the present embodiment, there are mixed inorganic fillers having at least two peak particle diameters (higher peaks=maximum values), respectively representing an inorganic filler having a relatively small particle diameter and an inorganic filler having a relatively large particle diameter. The use of an inorganic filler of a small particle diameter only or an inorganic filler of a large particle diameter only hardly enables a concurrent attainment of a high thermal conductivity and a high peel strength in a cured product of a resin composition. Additionally, when only an inorganic filler of a small particle diameter is contained, the thermal conductivity and the heat resistance of a cured product of the obtained resin composition are liable to be hardly enhanced enough. Further, when only an inorganic filler of a large particle diameter is contained, the moldability of the obtained resin composition is liable to decrease.

In the present specification, the particle size distribution indicates values on a particle size distribution measurement of the laser diffraction-scattering method. The values are obtainable, for example, by a Wet Particle Size Distribution Analyzer (“SALD-2100”), which is manufactured by the Shimadzu Corporation and is used in Examples described below. In the present embodiment, the peak indicates a maximum value in a graph of the particle size distribution. Specifically, the peak is represented by a numerical value obtained as a maximum value in a graph of the particle size distribution where the horizontal axis indicates a particle diameter and the vertical axis indicates a relative particle amount (frequency).

Further, it is preferable that a cumulative proportion of particles in a particle diameter range of 0.1 to 5.0 μm is 20 to 80% and a cumulative proportion of particles in a particle diameter range of 5.0 to 150.0 μm is 20 to 80%, relative to total particle size distribution of the inorganic filler as 100%. Each of the cumulative proportions (%) indicates a value obtainable through the calculation of a cumulative value of a relative particle amount in each particle diameter range.

More preferably, the boron nitride contained in the inorganic filler according to the present embodiment satisfies that, when the boron nitrides are discriminated by an Energy-Dispersive X-Ray analysis (under an observation by an EDX analysis) of a vertical cross-section of a cured product of the resin composition according to the present embodiment, 3 to 30 boron nitrides result in having a maximum length, from one end to another of the boron nitride, of 10 μm or more and 50 μm or less among the boron nitrides present in an area of a square with a side of 50 μm under an observation by a scanning electron microscope. This has an advantage that a copper foil peel strength can be ensured while a high thermal conductivity is maintained.

The resin composition according to the present embodiment may contain only the boron nitride, or may include an inorganic filler other than the boron nitride.

When only the boron nitride is contained, two or more kinds of boron nitrides having different particle diameters therebetween are used such that the particle size distribution of the inorganic filler meets the requirements provided above. Further, when an inorganic filler other than the boron nitride is contained, a particle diameter of the boron nitride and a particle diameter of an inorganic filler other than the boron nitride may be respectively adjusted such that the particle size distribution of the inorganic filler meets the requirements provided above.

The inorganic filler other than the boron nitride is not particularly limited as long as it can be used as an inorganic filler contained in a resin composition. Specific examples of the inorganic filler other than the boron nitride include silica, alumina, titanium oxide, a metal oxide such as magnesium oxide and mica, metal hydroxides such as aluminum hydroxide and magnesium hydroxide, talc, aluminum borate, barium sulfate, aluminum nitride, silicon nitride, magnesium carbonate such as anhydrous magnesium carbonate, and calcium carbonate. Among these, the silica, the anhydrous magnesium carbonate, the alumina, and the silicon nitride are preferable as an inorganic filler other than the boron nitride. The silica is not particularly limited, and examples thereof include fractured silica and granular silica, where the granular silica is preferable. The magnesium carbonate is not particularly limited, but the anhydrous magnesium carbonate (synthetic magnesite) is preferable.

The inorganic filler other than the boron nitride may be either a surface treated inorganic filler or a non-surface treated inorganic filler. Examples of the surface treatment include a treatment with a silane coupling agent.

Examples of the silane coupling agent include a silane coupling agent having at least one functional group selected from a group consisting of a vinyl group, a styryl group, a methacryloyl group, an acryloyl group, and a phenylamino group. Specifically, examples of the silane coupling agent include a compound having at least one of the vinyl group, the styryl group, the methacryloyl group, the acryloyl group, and the phenylamino group as a reactive functional group, and further having a hydrolyzable group such as a methoxy group or an ethoxy group.

Examples of the silane coupling agent include vinyltriethoxysilane and vinyltrimethoxysilane as the silane coupling agent having the vinyl group. Examples of the silane coupling agent include p-styryltrimethoxysilane and p-styryltriethoxysilane as the silane coupling agent having the styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as the silane coupling agent having the methacryloyl group. Examples of the silane coupling agent include 3-acryloxypropyltrimethoxysilane and 3-acryloxypropyltriethoxysilane as the silane coupling agent having the acryloyl group. Examples of the silane coupling agent include n-phenyl-3-aminopropyltrimethoxysilane and n-phenyl-3-aminopropyltriethoxysilane as the silane coupling agent having the phenylamino group.

Besides, when the inorganic filler according to the present embodiment includes an inorganic filler other than the boron nitride, a content of the boron nitride in the inorganic filler is preferably 25 to 80 parts by volume relative to 100 parts by volume of the inorganic filler. This is considered to more reliably ensure a high thermal conductivity. A more preferable range covers 30 to 70 parts by volume.

In the present embodiment, an average particle diameter of the boron nitride and/or an average particle diameter of an inorganic filler other than the boron nitride are not particularly limited as long as a particle size distribution of the inorganic filler according to the present embodiment meets the requirements provided above.

In the inorganic filler according to the present embodiment, a particle size distribution may have not only the peaks in the particle diameter range of 0.8 to 5.0 μm and in the particle diameter range of 5.0 to 30.0 μm, but also a further third peak in another particle diameter range. In this case, the third peak is preferably present in a particle diameter range of 0.1 to 0.8 μm. This enables a more homogeneous dispersion of the filler in the resin component, which promises a further advantage, i.e., an enhancement of the thermal conductivity.

In a more preferable embodiment, the resin composition according to the embodiment preferably contains the boron nitride and silica as the inorganic filler. Further, it is more preferable that a particle size distribution of the inorganic filler containing the boron nitride and the silica, which is measured by the laser diffraction-based particle size distribution measuring method, has at least three peaks in the particle diameter range of 0.8 to 30.0 μm, the peaks including at least one peak in the particle diameter range of 0.8 to 5.0 μm, at least one peak in the particle diameter range of 5.0 to 30.0 μm, and at least one peak in a particle diameter range of 0.1 to 0.8 μm. In this case, the particle size distribution of the inorganic filler according to the present embodiment has at least three peaks, where the particle size distribution is preferably adjusted by making the inorganic filler contain at least two kinds of boron nitrides having different particle diameters therebetween and silica. This configuration is considered to bring an advantage, i.e., an enhancement of the thermal conductivity owing to the homogeneous dispersion of a highly thermal conductive filler in the resin component.

Styrene-based Polymer The resin composition according to the present embodiment may further include a styrene-based polymer other than the components described above. A considerable advantage of including a styrene-based polymer is in further lowering the dielectric constant in a cured product of the resin composition.

The styrene-based polymer used in the present embodiment is, for example, a polymer obtained by polymerizing a monomer including a styrene-based monomer, and may be a styrene-based copolymer. Examples of the styrene-based copolymer include a copolymer obtained by copolymerizing one or more kinds of styrene-based monomer with one or more kinds of other monomer copolymerizable with a styrene-based monomer. Examples of the styrene-based monomer includes styrene, a styrene derivative, styrene resulting from the substitution of a part of hydrogen atoms thereof with a substituent.

As a specific styrene-based polymer, a conventionally-known one may be broadly used, and the styrene-based polymer is not particularly limited, but examples thereof include a polymer having a structural unit (a structure derived from a styrene-based monomer) expressed by the following formula (3) in the molecule.

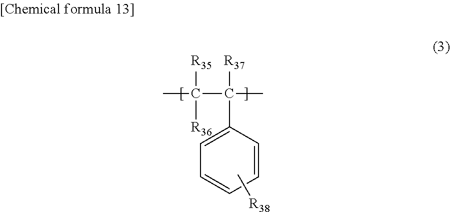

In formula (3), R₃₅ to R₃₇ each independently represents a hydrogen atom or an alkyl group, and R₃₈ represents a group selected from a group consisting of a hydrogen atom, an alkyl group, an alkenyl group, and an isopropenyl group. The alkyl group is not particularly limited, and for example, an alkyl group having 1 to 18 carbon atoms is preferable, and an alkyl group having 1 to 10 carbon atoms is more preferable. The alkenyl group is preferably an alkenyl group having 1 to 10 carbon atoms. Specific examples thereof include a methyl group, an ethyl group, a propyl group, a hexyl group, and a decyl group.

The styrene-based polymer according to the present embodiment preferably includes at least one kind of structural unit expressed by the formula (3), but may include two or more different kinds thereof in combination. Further, it is preferable to include a structure where the structural unit expressed by the formula (3) is repeated.

Further, as the other monomer copolymerizable with the styrene-based monomer, the styrene-based polymer according to the present embodiment may include, in addition to a structural unit expressed by the formula (3), at least one among the structural units expressed by the following formulas (4), (17), and (18) and repeating structures where the structural units expressed by the formulas (4), (17), and (18) are respectively repeated.

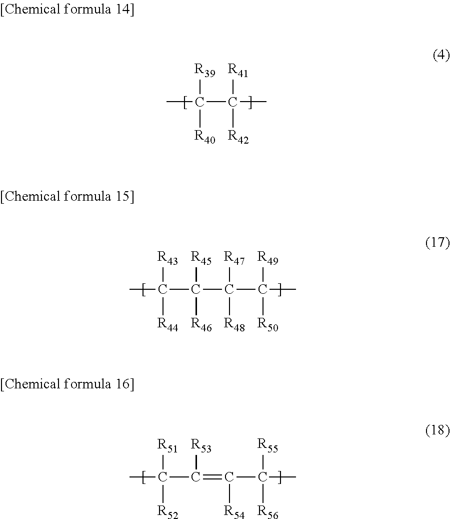

In the formulas (4), (17), and (18), R₃₉ to R₅₆ each independently represents any group selected from the group consisting of a hydrogen atom, an alkyl group, an alkenyl group, and an isopropenyl group. The alkyl group is not particularly limited, and for example, an alkyl group having 1 to 18 carbon atoms is preferable, and an alkyl group having 1 to 10 carbon atoms is more preferable. Specific examples thereof include a methyl group, an ethyl group, a propyl group, a hexyl group, and a decyl group. The alkenyl group is preferably an alkenyl group having 1 to 10 carbon atoms. The styrene-based polymer according to the present embodiment preferably includes at least one kind among the structural units expressed by the formulas (4), (17), and (18), but may include two or more different kinds thereof in combination. Further, it may include a structure where a structural unit expressed by the formulas (4), (17), and/or (18) is repeated.

Further, more specific examples of the structural unit expressed by the formula (3) include structural units expressed by the following formulas (19) to (21), and structures where the structural units expressed by the formulas (19) to (21) are respectively repeated. The styrene-based polymer according to the present embodiment is not particularly limited, but preferably include one or more kinds selected from repeating structures where the structural units expressed by the formulas (19) to (21) are respectively repeated.

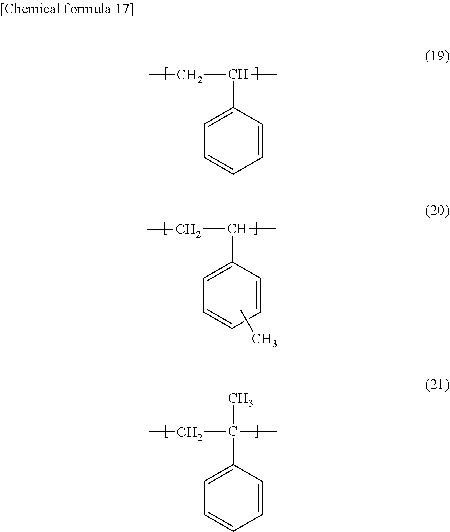

More specific examples of the structural unit expressed by the formula (4) include structural units expressed by the following formulas (5), (22) to (27), and structures where the structural units expressed by the formulas (22) to (27) are respectively repeated. When the styrene-based polymer according to the present embodiment includes a structural unit expressed by the formula (4), the styrene-based polymer is not particularly limited but preferably includes one or more kinds selected from the group of repeating structures where the structural units expressed by the formulas (5), (22) to (27) are respectively repeated, and more preferably includes the formula (5).

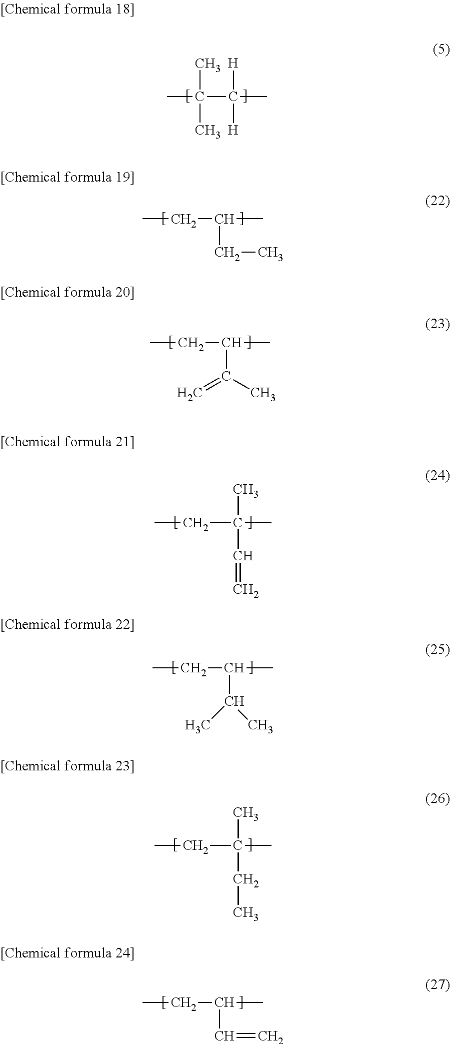

More specific examples of the structural unit expressed by the formula (17) include structural units expressed by the following formulas (28) to (29) and structures where the structural units expressed by the formulas (28) to (29) are respectively repeated. When the styrene-based polymer according to the present embodiment includes a structural unit expressed by the formula (17), the styrene-based polymer is not particularly limited but preferably includes one or more kinds selected from the group of repeating structures where the structural units expressed by the formulas (28) to (29) are respectively repeated.

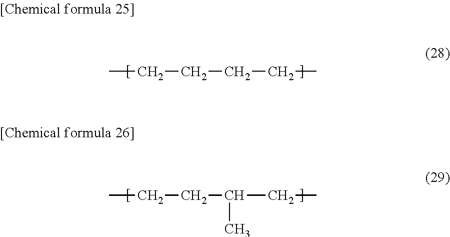

More specific examples of the structural unit expressed by the formula (18) include structural units expressed by the following formulas (30) to (31), and structures where the structural units expressed by the formulas (30) to (31) are respectively repeated. When the styrene-based polymer according to the present embodiment includes a structural unit expressed by the formula (18), the styrene-based polymer is not particularly limited, but preferably includes one or more kinds selected from the group of repeating structures where the structural units expressed by the formulas (30) to (31) are respectively repeated.

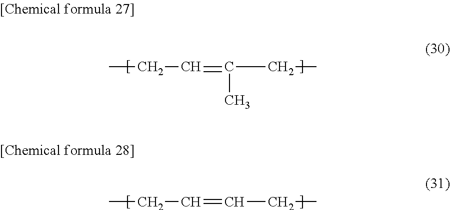

Preferable examples of the styrene-based polymer include a polymer or a copolymer obtained by polymerizing or copolymerizing one or more kinds of the styrene-based monomer, e.g., styrene, vinyltoluene, α-metylstyrene, isopropenyl toluene, divinylbenzene, and allylstyrene. More specific examples thereof include a styrene-butadiene copolymer and a styrene-isobutylene copolymer. Also, the styrene-based polymer may be a polymer of styrene obtained by an addition of hydrogen (i.e., hydrogenated), and examples thereof include a hydrogenated methylstyrene (ethylene/butylene) methylstyrene copolymer, a hydrogenated methyl styrene (ethylene-ethylene/propylene) methylstyrene copolymer, a hydrogenated styrene isoprene copolymer, a hydrogenated styrene isoprene styrene copolymer, a hydrogenated styrene (ethylene/butylene) styrene copolymer, and a hydrogenated styrene (ethylene-ethylene/propylene) styrene copolymer.

As the styrene-based polymer, the polymers exemplified above may be used singly or in combination of two or more kinds thereof.

The inclusion of the styrene-based polymer can give, in addition to the effects described above, further effects of suppressing the moisture absorption in a cured product of the resin composition and suppressing the degradation of the electric properties caused by an increase in the moisture absorption.

When the styrene-based polymer according to a preferable embodiment includes at least one kind of the structural units expressed by the formulas (19) to (21), a mole fraction of the structural unit is preferably roughly 10 to 70%, more preferably 15 to 65% of the entire polymer. As a result, the compatibility with the resin can be maintained, and thus there is a further advantage that the homogeneity of the properties in the resin composition can be maintained.

The polymer morphology of the styrene-based polymer is not particularly limited, and may include a block copolymer, an alternating copolymer, a random copolymer, and a graft copolymer. Besides, the polymer may be in the form of an elastomer.

The styrene-based polymer according to the present embodiment preferably has a weight average molecular weight and a number average molecular weight of substantially 10,000 to 200,000, and more preferably 20,000 to 150,000. When the average molecular weights fall within the above range, there is an advantage that a proper resin fluidity can be secured in a cured resin product at the B-stage. The weight average molecular weight and the number average molecular weight here may be measured by a general molecular weight measurement method, and specific examples thereof include a value measured by gel permeation chromatography.

In the preferred embodiment, the styrene-based polymer desirably includes a styrene-isobutylene-styrene block copolymer (SIBS) having a structural unit expressed by the following formula (16). This enables an obtainment of a resin composition having high gas barrier properties, which brings an advantage that the moisture absorption can be suppressed in the resin composition.

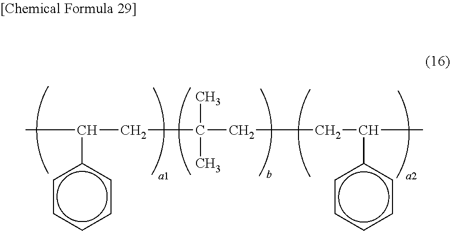

In formula (16), the sum of a1 and a2 is an integer of 1,000 to 60,000, b denotes an integer of 1,000 to 70,000, and the sum of a1, a2, and b is 10,000 to 130,000.

A method for preparing a styrene-based polymer used in the present embodiment is not particularly limited, but an exemplary method for preparing the SIBS will be described. It can be synthesized by first polymerizing isobutylene according to Living cationic polymerization method, and thereafter still polymerizing by adding the styrene thereto.

As the styrene-based polymer according to the present embodiment, a commercially-available one can be also used, and examples thereof include “SIBSTAR (registered trademark) 073T”, “SIBSTAR (registered trademark) 103T”, “SIBSTAR (registered trademark) 102T” which are manufactured by Kaneka Corporation, and “Septon V9827” manufactured by Kuraray Co., Ltd.

Content of each component The content of the polyphenylene ether compound in the resin composition according to the present embodiment is preferably 50 to 90 parts by mass, more preferably 55 to 85 parts by mass, and still more preferably 60 to 80 parts by mass relative to 100 parts by mass of the total of the polyphenylene ether compound and the curing agent (and the styrene-based polymer when the styrene-based polymer is contained). In other words, the content of the polyphenylene ether compound is preferably 50 to 90 mass % of the components of the resin composition other than the inorganic filler. It is considered that a resin composition, from which a cured product having low dielectric characteristics and a high heat resistance is obtainable, can be more reliably attained when the content of the polyphenylene ether compound is within the above range.

The content of the curing agent is preferably 10 to 40 parts by mass, and more preferably 15 to 35 parts by mass relative to 100 parts by mass of the total of the polyphenylene ether compound and the curing agent (and the styrene-based polymer when the styrene-based polymer is contained) in the resin composition. When the content of the curing agent falls within the above range, the resulting resin composition can become a cured product having more excellent heat resistance. This is considered to be because the curing reaction between the resin component and the curing agent according to the present embodiment suitably proceeds.

The content of the inorganic filler in the resin composition according to the present embodiment is 20 to 60 parts by volume relative to 100 parts by volume of a total of the polyphenylene ether compound, the curing agent, (the styrene-based polymer when the styrene-based polymer is contained,) and the inorganic filler. Further, the content of the inorganic filler (i.e., filler contents) is preferably 20 to 60 parts by volume relative to 100 parts by volume of the resin composition. More preferable content is 25 to 55 parts by volume. Presumably, when the content is less than 20 parts by volume, a sufficient thermal conductivity is hardly obtainable, and on the other hand, when the content is more than 60 parts by volume, the moldability decreases. In other words, when the content of the inorganic filler is within the above range, it is possible to provide a resin composition from which a cured product having a high thermal conductivity is obtainable, the resin composition further having an excellent moldability.

The content of the boron nitride in the resin composition according to the present embodiment is preferably 15 to 30 parts by volume relative to 100 parts by volume of a total of the resin components (the polyphenylene ether compound, the curing agent, and the styrene-based polymer when the styrene-based polymer is contained), and the inorganic filler. This is considered to more reliably ensure a high thermal conductivity.

When the resin composition according to the present embodiment contains the inorganic filler other than the boron nitride, the content of the inorganic filler other than the boron nitride in the resin composition is preferably 5 to 40 parts by volume, more preferably 15 to 30 parts by volume relative to 100 parts by volume of the total of the resin components (the polyphenylene ether compound, the curing agent, and the styrene-based polymer when the styrene-based polymer is contained), and the inorganic filler. This is considered to ensure the copper foil peel strength while maintaining a high thermal conductivity.

Further, when the resin composition according to the present embodiment contains the styrene-based polymer, the content of the styrene-based polymer is preferably 5 to 25 parts by mass, and more preferably 10 to 20 parts by mass relative to 100 parts by mass of the total of the polyphenylene ether compound, the curing agent, and the styrene-based polymer in the resin composition.

Other Component The resin composition according to the present embodiment may contain a component (another component) other than the components described above without impairing the effect of the present invention, if necessary. Examples of such a component contained in the resin composition according to the present embodiment may further include an additive, such as a reaction initiator, a silane coupling agent, a flame retardant, a defoaming agent, an antioxidant, a thermal stabilizer, an antistatic agent, an ultraviolet absorber, a dye, a pigment, a dispersant, and a lubricant. The resin composition according to the present embodiment may contain another thermosetting resin, such as an epoxy resin, a maleimide resin, an aromatic hydrocarbon resin, and an aliphatic hydrocarbon resin other than the polyphenylene ether compound, the curing agent, and the polymer.

As described above, the resin composition according to the present embodiment may contain a reaction initiator (initiator). The curing reaction can proceed even when the resin composition contains the polyphenylene ether compound, the curing agent, and the polymer. However, a reaction initiator may be added since there is a case where it is difficult to raise the temperature until curing proceeds depending on the process conditions.

The reaction initiator is not particularly limited as long as the reaction initiator can promote the curing reaction in the resin composition. Specific examples thereof include a metal oxide, an azo compound, and an organic peroxide.

Specific examples of the metal oxide include metal carboxylate.

Specific examples of the organic peroxide include α, α′-di(t-butylperoxy)diisopropylbenzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile.

Specific examples of the azo compound include 2,2′-azobis(2,4,4-trimethylpentane), 2,2′-azobis(n-butyl-2-methylpropionamide), 2,2′-azobis(2-methylbutyronitrile)

Among these, 2,2′-azobis(2,4,4-trimethylpentane), 2,2′-azobis(n-butyl-2-methylpropionamide) are the preferable reaction initiators. These reaction initiators barely affect the dielectric characteristics. Additionally, these have relatively high reaction initiation temperatures, and thus have advantages that the promotion of the curing reaction can be suppressed at the time point at which curing is not required, for example, at the time of prepreg drying, and that a decrease in the storage stability of the resin composition can be suppressed.

The reaction initiators described above may be used singly or in combination of two or more kinds thereof.

When the resin composition according to the present embodiment contains the reaction initiator, the content thereof is not particularly limited, and is, for example, preferably 0.5 to 2.0 parts by mass, more preferably 0.8 to 1.5 parts by mass, and still more preferably 0.9 to 1.0 parts by mass relative to 100 parts by mass of a total of the polyphenylene ether compound, the curing agent, and the styrene-based polymer.

Production Method

The production method of the resin composition is not particularly limited, but examples thereof include a method including mixing the polyphenylene ether compound, the curing agent, and other organic components as needed, and thereafter, adding an inorganic filler thereto. Specific examples of the case of obtaining a varnish-like composition containing an organic solvent include a method specified in the following description of the prepreg.

Further, a prepreg, a metal-clad laminate, a wiring board, a metal foil with a resin, a film with a resin are obtainable as described below by use of the resin composition according to the present embodiment.

A cured product of the resin composition preferably has a thermal conductivity of 1.0 W/m·K or more, and a relative dielectric constant at a frequency of 10 GHz of 4.0 or less. As described above, the use of the resin composition according to the present embodiment enables a concurrent attainment of a high thermal conductivity and low dielectric characteristics and further an attainment of a high peel strength in a cured product thereof.

Prepreg

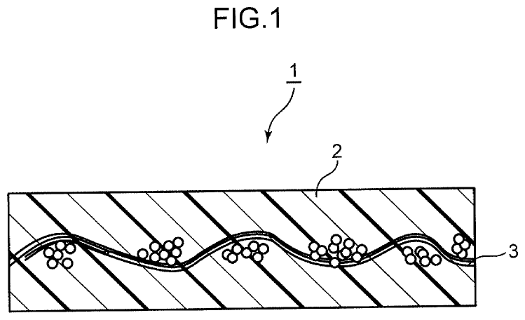

FIG. 1 is a schematic cross-sectional view showing an example of a prepreg 1 according to an embodiment of the present invention. In the description hereinafter, reference numerals respectively indicate: a prepreg 1, a resin composition 2 or a semi-cured product of the resin composition, a fibrous base material 3, a metal-clad laminate 11, an insulating layer 12, a metal foil 13, wiring 14, a wiring board 21, a metal foil with a resin 31, a resin layer 32, 42, a film with a resin 41, and a support film 43.

As shown in FIG. 1, the prepreg 1 according to the present embodiment includes the resin composition 2 or a semi-cured product of the resin composition and the fibrous base material 3. The prepreg 1 includes the resin composition 2 or the semi-cured product of the resin composition, and the fibrous base material 3 which is present in the resin composition 2 or the semi-cured product of the resin composition.

In the present embodiment, the semi-cured product is in a state in which the resin composition is cured to such a degree as to be further curable. Specifically, the semi-cured product is in a state in which the resin composition is semi-cured (B-staged). For example, when a resin composition is heated, first, the viscosity of the resin composition gradually decreases, and thereafter, curing begins, and thereafter, curing begins, and the viscosity gradually increases. In this case, the semi-curing state covers a state from the beginning of the increase in the viscosity until a stage before the completion of the curing.

The prepreg obtained by use of the resin composition according to the present embodiment may include a semi-cured product of the resin composition as described above, or may include an uncured resin composition itself. Specifically, the prepreg may include a semi-cured product of the resin composition (the B-stage resin composition) and a fibrous base material, or include the resin composition to be cured (the A-stage resin composition) and a fibrous base material. The resin composition or the semi-cured product of the resin composition may be obtained by drying, or heating and drying the resin composition.

When manufacturing a prepreg, the resin composition 2 is often prepared in a varnish form, and then used to impregnate the fibrous base material 3 being a base material constituting the prepreg. In other words, generally, the resin composition 2 is often a resin varnish prepared in the form of a varnish. The varnish-like resin composition (resin varnish) is prepared, for example, as follows.

First, components of the resin composition which are dissolvable in an organic solvent are introduced in the organic solvent to be thereby dissolved. At this time, heating may be performed if necessary. Thereafter, components which are used as needed and are not dissolvable in the organic solvent (e.g., an inorganic filler) are added thereto to be thereby dispersed until reaching a predetermined dispersion state using a ball mill, a bead mill, a planetary mixer, a roll mill or the like. A varnish-like resin composition is thus prepared. The organic solvent used here is not particularly limited as long as the organic solvent dissolves the modified polyphenylene ether compound, the curing agent, and the like, and does not inhibit the curing reaction. Specific examples thereof include toluene and methyl ethyl ketone (MEK).

The method for manufacturing the prepreg is not particularly limited as long as the prepreg can be manufactured. Specifically, when manufacturing a prepreg, the resin composition which is described above and is used in the present embodiment is often prepared in a varnish form and used as a resin varnish as described above.

Specific examples of the fibrous base material include a glass cloth, an aramid cloth, a polyester cloth, a nonwoven glass fabric, a nonwoven aramid fabric, a nonwoven polyester fabric, pulp paper, and linter paper. When a glass cloth is used, a laminate having an excellent mechanical strength can be obtained, where a glass cloth having undergone a flattening process is particularly preferable. Examples of the flattening process include a process of continuously pressurizing the glass cloth at an appropriate pressure by using a press roll to thereby compress the yarn to be flat. A commonly used thickness of the fibrous base material is, for example, 0.01 mm or more and 0.3 mm or less.

The method for manufacturing the prepreg is not particularly limited as long as the prepreg can be manufactured. Specifically, when manufacturing a prepreg, the resin composition which is described above and is according to the present embodiment is often prepared in a varnish form and used as a resin varnish as described above.

Examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 80° C. or more and 180° C. or less for 1 minute or more and 10 minutes or less. By heating, the prepreg 1 to be cured (A-stage) or in a semi-cured state (B-stage) is obtained. The heating can volatize the organic solvent from the resin varnish to thereby reduce or remove the organic solvent.

From a prepreg including a resin composition according the present embodiment or a semi-cured product of the resin composition, a cured product having low dielectric characteristics, a high thermal conductivity, and an excellent peel strength can be suitably obtained.

Metal-Clad Laminate

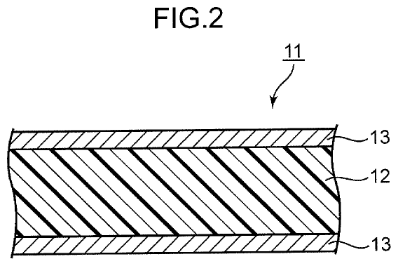

FIG. 2 is a schematic cross-sectional view showing an example of the metal-clad laminate 11 according to an embodiment of the present invention.

As shown in FIG. 2, a metal-clad laminate 11 includes an insulating layer 12 containing a cured product of the prepreg 1 shown in FIG. 1, and a metal foil 13 laminated with the insulating layer 12. Specifically, the metal-clad laminate 11 includes the insulating layer 12 containing the cured product of the resin composition, and the metal foil 13 provided over the insulating layer 12. The insulating layer 12 may contain a cured product of the resin composition, or may contain a cured product of the prepreg. The thickness of the metal foil 13 is not particularly limited because it varies depending on the properties required for a wiring board and the like to be finally obtained. The thickness of the metal foil 13 may be properly set according to a desired purpose, and for example, is preferably 0.2 to 70 μm. Examples of the metal foil 13 include a copper foil and an aluminum foil, and an exemplary thin metal foil may be in the form of a copper foil with a carrier including a peelable layer and the carrier in order to improve the handleability.

The method for manufacturing the metal-clad laminate 11 is not particularly limited as long as the metal-clad laminate 11 can be manufactured. Specific examples thereof include a method of manufacturing a metal-clad laminate 11 by use of the prepreg 1. Examples of this method includes: stacking one or a plurality of prepregs 1; placing a metal foil 13 such as a copper foil over either both upper and lower surfaces or one of the surfaces of the prepreg 1; and heating, pressurizing, and molding the metal foil 13 and the prepreg 1 to be integrally laminated, thereby manufacturing a double-sided metal foil-clad or single-sided metal foil-clad laminate 11. In other words, the metal-clad laminate 11 is obtainable by laminating the metal foil 13 over the prepreg 1 and heating, pressurizing, and molding the laminate. The heating and pressurizing conditions can be appropriately set depending on the thickness of the metal-clad laminate 11 to be manufactured and the type of the composition and the like of the prepreg 1. For example, the temperature can be set to the range of 170 to 210° C., the pressure can be set to the range of 3.5 to 4 MPa, and the time can be set to the range of 60 to 150 minutes. The metal-clad laminate may be manufactured without using a prepreg. For example, there is a way of applying a varnish-like resin composition on a metal foil to form a layer containing the resin composition on the metal foil, and thereafter performing the heating and pressurizing.

The metal-clad laminate including an insulating layer containing a cured product of the resin composition according to the present embodiment is a metal-clad laminate including an insulating layer having low dielectric characteristics, a high thermal conductivity, and an excellent peel strength.

Wiring Board

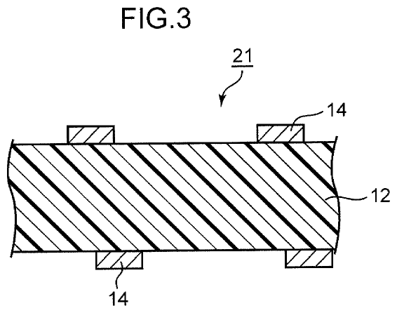

FIG. 3 is a schematic cross-sectional view showing an example of the wiring board 21 according to an embodiment of the present invention.

As shown in FIG. 3, a wiring board 21 according to the present embodiment includes an insulating layer 12 obtained by curing the prepreg 1 shown in FIG. 1, and wiring 14 which is laminated with the insulating layer 12 and is obtained by partly removing the metal foil 13. In other words, the wiring board 21 includes the insulating layer 12 containing the cured product of the resin composition and wiring 14 provided on the insulating layer 12. The insulating layer 12 may contain a cured product of the resin composition, or a cured product of the prepreg.

The method for manufacturing the wiring board 21 is not particularly limited as long as the wiring board 21 can be manufactured. Specific examples thereof include a method of manufacturing a wiring board 21 by use of the prepreg 1. Examples of the method include etching the metal foil 13 on the surface of the metal-clad laminate 11 prepared in the above-described manner to form wiring serving as a circuit on a surface of the insulating layer 12. In this way, the wiring board 21 provided with the wiring is manufactured. In other words, the wiring board 21 is obtainable by partly removing the metal foil 13 on the surface of the metal-clad laminate 11 to form the circuit. Examples of ways of forming a circuit include, other than the way described above, a circuit formation according to Semi Additive Process (SAP) and Modified Semi Additive Process (MSAP). The wiring board 21 includes an insulating layer 12 which has low dielectric characteristics, a high heat resistance, and can suitably maintain the low dielectric characteristics even after having undergone a water absorption process.

The wiring board includes an insulating layer having low dielectric characteristics, a high thermal conductivity, and an excellent peel strength.

Metal Foil with a Resin

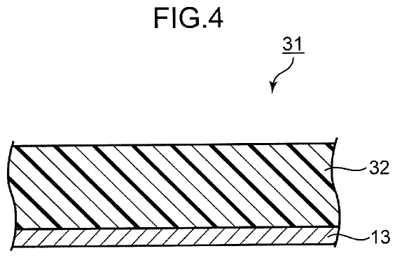

FIG. 4 is a schematic cross-sectional view showing an example of the metal foil with a resin 31 according to an embodiment of the present invention.

As shown in FIG. 4, a metal foil with a resin 31 according to the present embodiment includes a resin layer 32 containing the resin composition or a semi-cured product of the resin composition and a metal foil 13. The metal foil with a resin 31 includes a metal foil 13 on a surface of the resin layer 32. In other words, this metal foil with a resin 31 includes the resin layer 32, and the metal foil 13 laminated with the resin layer 32. The metal foil with a resin 31 may include another layer between the resin layer 32 and the metal foil 13.

The resin layer 32 may contain a semi-cured product of the resin composition as described above, or may contain an uncured resin composition itself. Specifically, the metal foil with a resin 31 may include a resin layer containing a semi-cured product of the resin composition (the B-stage resin composition) and a metal foil, or include a resin layer containing the resin composition to be cured (the A-stage resin composition) and a metal foil. It is sufficient that the resin layer contains the resin composition or a semi-cured product of the resin composition, and may or may not contain a fibrous base material. The resin composition or the semi-cured product of the resin composition may be obtained by drying, or heating and drying the resin composition. The same fibrous base material as that of the prepreg may be used as the fibrous base material.

As the metal foil, a metal foil used for a metal-clad laminate may be used without a limitation. Examples of the metal foil include a copper foil and an aluminum foil.

The metal foil with a resin 31 and the film with a resin 41 may include a cover film as needed. The cover film included therein can prevent an infiltration of a foreign matter and the like. The cover film is not particularly limited, but examples thereof include a polyolefin film, a polyester film, a polymethylpentene film, and each of the films formed with a release agent layer.

The method for manufacturing the metal foil with a resin 31 is not particularly limited as long as the metal foil with a resin 31 can be manufactured. Examples of the method for manufacturing the metal foil with a resin 31 include a manufacturing method including applying the varnish-like resin composition (resin varnish) over the metal foil 13, and thereafter performing the heating. The varnish-like resin composition is applied over the metal foil 13, for example, by use of a bar coater. The applied resin composition is heated under conditions, for example, at 80° C. or more and 180° C. or less for 1 minute or more and 10 minutes or less. The heated resin composition is formed on the metal foil 13 as an uncured resin layer 32. The heating can volatize the organic solvent from the resin varnish to thereby reduce or remove the organic solvent.

From a metal foil with a resin including a resin layer containing the resin composition according to the present embodiment or a semi-cured product of the resin composition, a cured product having low dielectric characteristics, a high thermal conductivity, and an excellent peel strength can be suitably obtained.

Film with a Resin

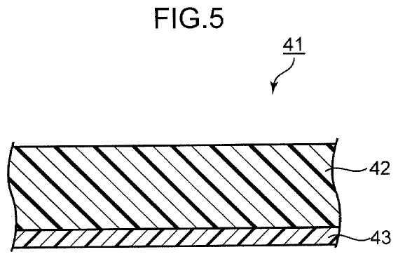

FIG. 5 is a schematic cross-sectional view showing an example of a film with a resin 41 according to an embodiment of the present invention.

As shown in FIG. 5, a film with a resin 41 according to the present embodiment includes a resin layer 42 containing the resin composition or a semi-cured product of the resin composition, and a support film 43. The film with a resin 41 includes the resin layer 42, and the support film 43 laminated with the resin layer 42. The film with a resin 41 may include another layer between the resin layer 42 and the support film 43.

The resin layer 42 may contain a semi-cured product of the resin composition as described above, or may contain an uncured resin composition itself. Specifically, the film with a resin 41 may include a resin layer containing a semi-cured product of the resin composition (the B-stage resin composition) and a support film, or include a resin layer containing the resin composition to be cured (the A-stage resin composition) and a support film. It is sufficient that the resin layer contains the resin composition or a semi-cured product of the resin composition, and may or may not contain a fibrous base material. The resin composition or the semi-cured product of the resin composition may be obtained by drying, or heating and drying the resin composition. The same fibrous base material as that of the prepreg may be used as the fibrous base material.

As the support film 43, a support film used for a film with a resin may be used without a limitation. Examples of the support film include electrical insulating films such as a polyester film, a polyethylene terephthalate (PET) film, a polyimide film, a polyparabanic acid film, a polyetheretherketone film, a polyphenylene sulfide film, a polyamide film, a polycarbonate film, and a polyarylate film.

The film with a resin 41 may include a cover film as needed. The cover film included therein can prevent an infiltration of a foreign matter and the like. The cover film is not particularly limited, but examples thereof include a polyolefin film, a polyester film, and a polymethylpentene film.

As the support film and the cover film, the one having undergone a surface treatment such as a matt finishing, a corona treatment, a releasing treatment, and a roughening treatment can be used as needed.

The method for manufacturing the film with a resin 41 is not particularly limited as long as the film with a resin 41 can be manufactured. Examples of the method for manufacturing the film with a resin 41 include a manufacturing method including applying the varnish-like resin composition (resin varnish) over the support film 43, and thereafter performing the heating. The varnish-like resin composition is applied over the support film 43, for example, using a bar coater. The applied resin composition is heated under conditions, for example, at 80° C. or more and 180° C. or less for 1 minute or more and 10 minutes or less. The heated resin composition is formed on the support film 43 as an uncured resin layer 42. The heating can volatize the organic solvent from the resin varnish to thereby reduce or remove the organic solvent.

From a film with a resin including a resin layer containing the resin composition according to the present embodiment or a semi-cured product of the resin composition, a cured product having low dielectric characteristics, a high thermal conductivity, and an excellent peel strength can be suitably obtained. Further, the film with a resin has an excellent moldability.

The present invention will be further specifically described by way of Examples hereinafter. However, the scope of the present invention is not limited thereto.

### EXAMPLES

### Examples 1 to 14, Comparative Examples 1 to 3

Each component used in preparing the resin composition in the Examples will be described. A specific gravity of each component is a value relative to pure water as the reference substance.

Polyphenylene Ether Compound

PPE 1: Polyphenylene ether compound having a methacryloyl group at a molecular end (a modified polyphenylene ether having a terminal hydroxyl group of the polyphenylene ether modified by a methacryloyl group, a modified polyphenylene ether compound expressed by the formula (15), where Y in the formula (15) represents a dimethylmethylene group (expressed by the formula (12), where R₃₃ and R₃₄ in the formula (12) represent a methyl group), SA9000 manufactured by SABIC Innovative Plastics IP BV, weight average molecular weight Mw: 2000, number of terminal functional groups: 2, specific gravity: 1.02) PPE 2 is modified polyphenylene ether obtained by causing polyphenylene ether and chloromethylstyrene to react with each other (specific gravity: 1.04). Specifically, the modified polyphenylene ether is obtained by causing a reaction in the following manner.

First, 200 g of polyphenylene ether (SA90 manufactured by SABIC Innovative Plastics IP BV, number of terminal hydroxyl groups: 2, weight average molecular weight Mw: 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Moreover, the mixture was stirred until polyphenylene ether, chloromethylstyrene, and tetra-n-butylammonium bromide were dissolved in toluene. At that time, the mixture was gradually heated until the liquid temperature finally reached 75° C. Thereafter, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10 mass % and then a large amount of methanol was added into the flask. This caused the generation of a precipitate in the liquid in the flask. In other words, the product contained in the reaction solution in the flask was reprecipitated. Thereafter, this precipitate was taken out by filtration, washed three times with a mixed solution of methanol and water contained at a mass ratio of 80:20, and then dried under reduced pressure at 80° C. for 3 hours.

The obtained solid was analyzed by ¹H-NMR (400 MHz, CDCl₃, TMS). As a result of NMR measurement, a peak attributed to a vinylbenzyl group (ethenylbenzyl group) was observed at 5 to 7 ppm. This made it possible to confirm that the obtained solid was a modified polyphenylene ether compound having a vinylbenzyl group (ethenylbenzyl group) as the substituent at the molecular terminal end in the molecule. Specifically, it was confirmed that the solid obtained was ethenylbenzylated polyphenylene ether. This obtained modified polyphenylene ether compound was a modified polyphenylene ether compound expressed by formula (14), where Y represents a dimethylmethylene group (a group expressed by formula (12), where R₃₃ and R₃₄ in formula (12) represent a methyl group), Z represents a phenylene group, R₁ to R₃ each represent a hydrogen atom, and n denotes 1.

The number of terminal functional groups in the modified polyphenylene ether was measured as follows.

First, the modified polyphenylene ether was accurately weighed. The weight at that time is defined as X (mg). Thereafter, this modified polyphenylene ether weighed was dissolved in 25 mL of methylene chloride, 100 μL of an ethanol solution of tetraethylammonium hydroxide (TEAH) at 10 mass % (TEAH:ethanol (volume ratio)=15:85) was added to the solution, and then the absorbance (Abs) of this mixture at 318 nm was measured using a UV spectrophotometer (UV-1600 manufactured by Shimadzu Corporation). Thereafter, the number of terminal hydroxyl groups in the modified polyphenylene ether was calculated from the measurement result using the following equation.

Residual OH amount (μmol/g)=[(25×Abs)/(ε×OPL×X)]×10⁶

Here, ε represents the extinction coefficient and is 4700 L/mol·cm. OPL represents the cell path length and is 1 cm.

Since the calculated residual OH amount (the number of terminal hydroxyl groups) in the modified polyphenylene ether is almost zero, it was found that the hydroxyl groups in the polyphenylene ether before being modified have almost been modified. From this fact, it was found that the number of terminal hydroxyl groups decreased from the number of terminal hydroxyl groups in polyphenylene ether before being modified is the number of terminal hydroxyl groups in polyphenylene ether before being modified. In other words, it was found that the number of terminal hydroxyl groups in polyphenylene ether before being modified is the number of terminal functional groups in the modified polyphenylene ether. That is, the number of terminal functional groups was two.

The intrinsic viscosity (IV) of the modified polyphenylene ether was measured in methylene chloride at 25° C. Specifically, the intrinsic viscosity (IV) of the modified polyphenylene ether was measured in a methylene chloride solution (liquid temperature: 25° C.) of the modified polyphenylene ether at 0.18 g/45 ml using a viscometer (AVS500 Visco System manufactured by SCHOTT Instruments GmbH). As a result, the intrinsic viscosity (IV) of the modified polyphenylene ether was 0.086 dl/g.

The molecular weight distribution of the modified polyphenylene ether was measured by GPC. Moreover, the weight average molecular weight (Mw) was calculated from the obtained molecular weight distribution. As a result, Mw was 2,300.

Curing Agent

TAIC: triallyl isocyanurate (TAIC manufactured by Nihon Kasei Co., Ltd), specific gravity: 1.15 DVB: divinylbenzene (manufactured by Nippon Steel & Sumitomo Metal Corporation), specific gravity: 0.91

Reaction Initiator

Peroxide Initiator: PBP (1,3-bis (butylperoxyisopropyl) benzene; Perbutyl P manufactured by NOF CORPORATION), specific gravity: 0.91

Styrene-Based Polymer

V9827: hydrogenated methylstyrene (ethylene/butylene) methylstyrene copolymer (Septon V9827 manufactured by Kuraray Co., Ltd, weight average molecular weight: 92,000), specific gravity: 0.93
SIBSTAR103T: Styrene-isobutylene-styrene-based triblock copolymer (manufactured by Kaneka Corporation, number average molecular weight: 85,000, mole fraction of styrene: 30%), specific gravity: 0.95

Inorganic Filler

Boron nitride 1: “AP-20S” manufactured by MARUKA Corporation, volume average particle diameter: 2.0 μm, specific gravity: 2.30
Boron nitride 2: “AP-10S” manufactured by MARUKA Corporation, volume average particle diameter: 3.0 μm, specific gravity: 2.30
Boron nitride 3: “MGP” manufactured by Denka Company Limited, volume average particle diameter: 13 μm, specific gravity: 2.30

Boron nitride 4: “SGP” manufactured by Denka Company Limited, volume average particle diameter: 18 μm, specific gravity: 2.30

Silica 1: “FB-7SDC” manufactured by Denka Company Limited, volume average particle diameter: 5 μm, specific gravity: 2.20
Silica 2: “SC2300-SVJ” manufactured by Admatechs Company Limited, volume average particle diameter: 0.5 μm, specific gravity: 2.20
Alumina: “DAW-03AC” manufactured by Denka Company Limited, volume average particle diameter: 8 μm, specific gravity: 3.92

Preparation Method

First, each organic resin component other than the inorganic filler was added to toluene as a solvent at a composition (parts by mass) shown in Tables 1 to 2 so as to have a solid content concentration of 60 to 70 mass % and mixed therewith. The mixture was stirred for 60 minutes. Thereafter, the obtained liquid was added with each filler in respective proportions (parts by volume) shown in Tables 1 and 2, and the inorganic filler was dispersed by a bead mill. As a result, a vanish resin composition (varnish) was obtained. The respective proportions of the content of the organic components other than the solvent (parts by volume), the boron nitride content (parts by volume), and the content of the inorganic filler other than the boron nitride (parts by volume) in each Example and Comparative Example are also shown in Tables 1 and 2.

Subsequently, Evaluation Substrate (cured product of prepreg) was obtained in the following manner.

A fibrous base material (glass cloth: #1078 type manufactured by Asahi Kasei Corporation, an L glass) was impregnated with the obtained varnish, and was then heated and dried at 110° C. for 3 minutes to manufacture a prepreg. Subsequently, one, two, or four stacked sheets of the obtained prepreg were each laminated with a copper foil (“FV-WS” manufactured by Furukawa Electric Co., Ltd., copper foil thickness: 35 μm) over both surfaces of the respective prepreg sheet, were heated to the temperature of 200° C. at a temperature raise rate of 4° C./min., were then heated and pressurized under conditions of the temperature of 200° C. and the pressure of 3 MPa for 120 minutes to manufacture copper-clad laminates of three thickness types.

The copper-clad laminates prepared in this way were used as Evaluation Substrates, and were evaluated in accordance with the method described below. Further, samples (cured products of prepreg) obtained by removing the respective copper foils from the cured product of one prepreg sheet and from the copper-clad laminate of two stacked prepreg sheets were used in the measurement of the thermal conductivity described below. The copper-clad laminate of four stacked prepreg sheets was used in the measurement of the peel strength. A sample (cured product of prepreg) obtained by removing the copper foils from the copper-clad laminate of four stacked prepreg sheets was used in the evaluation tests on the dielectric characteristics (relative dielectric constant).

Dielectric Characteristics (Relative Dielectric Constant)

The relative dielectric constant (Dk) of Evaluation Substrate (cured product of prepreg) at 10 GHz was measured in accordance with Cavity Resonator Perturbation Method. Specifically, the relative dielectric constant of Evaluation Substrate at 10 GHz was measured using a Network Analyzer (N5230A manufactured by Keysight Technologies Kabushiki Kaisha). The acceptance criterion in the present Example was Dk≤4.0.

Thermal Conductivity

The thermal conductivity of the obtained Evaluation Substrates (cured products of prepreg) was measured in a way in conformity with ASTM D5470. Specifically, a thermal property tester (T3Ster DynTIM Tester manufactured by Mentor Graphics Corporation) was used to measure a heat resistance and a thickness of the obtained Evaluation Substrates (a cured product of one prepreg sheet, a cured product of two stacked prepreg sheets). The measured values were plotted on a graph, were approximated by a straight line, and a thermal conductivity was calculated on the basis of an increase in the heat resistance and the thickness. The acceptance criterion of the thermal conductivity in the present Example was 1.0 W/m·K or more.

Peel Strength

First, a copper-clad laminate (CCL) was prepared using the prepregs of each Example and Comparative Example for the peel strength (copper foil peel) test. Specifically, four prepreg sheets were stacked one another, and a copper foil (“FV-WS” manufactured by Furukawa Electric Co., Ltd.) with a thickness of 35 μm was arranged on both surfaces of the prepreg, were heated and pressurized in a vacuum under conditions of the temperature of 200° C. and the pressure of 3 MPa for 120 minutes to obtain a copper-clad laminate (CCL) (Evaluation Substrate) including a copper foil adhered to both surfaces thereof and having a thickness of 580 μm.

Thereafter, a strength required for peeling off the copper foil from the insulating layer was measured using the obtained CCL in a way in conformity with JIS C 6481. A pattern with a width of 10 mm and a length of 100 mm was prepared, was peeled off by a peel tester at a speed of 50 mm/min., and a peel strength at that time was measured. The unit of measure was N/mm. The acceptance criterion of the peel strength in the present Example was 0.40 N/mm or more.

Particle Size Distribution of Inorganic Filler and Peak Thereof

A particle size distribution of the inorganic filler in each Example and Comparative Example was obtained through a measurement by a laser diffraction-based particle size distribution analyzer SALD-2100 (manufactured by the Shimadzu Corporation). The specifications of the analyzer are described below.
Measurement method: laser diffraction and laser scattering method
Measurement range: 0.03 μm to 1,000 μm
Light source: semiconductor laser (wavelength of 680 nm, output of 3 mW)
Receptive part: Optical sensor with 81 elements in total, including a 76-elements irregular concentric circle sensor, a side sensor, and a rear sensor (4 elements), refractive index: 1.70-0.20i

The specifications of a batch cell used for the measurement are described below.

External dimension (width×depth×height): 40 mm×90 mm×14 mm
Internal dimension (width×depth×height): 36 mm×88 mm×9 mm
Cell material: quartz glass
Stirrer mechanism: stirring by vertical movements of a stirring blade
Stirring blade material: SUS304

Conditions for the measurement of the particle size distribution are described below.

Each measurement sample was charged into the batch cell using toluene as dispersing solvent, and underwent a laser diffraction-based particle size distribution measurement in a stirred state.

The program Wing-1, which is a standard function of a software for analysis Wing SALD annexed to the SALD-2100 was used to analyze and calculate a particle size distribution.

Thereafter, a peak in the particle size distribution was obtained through a calculation using a volume proportion in the measured particle size distribution.

The results in the evaluations are shown in Tables 1 to 2.

TABLE 1

| | | | Example 1 | Example 2 | Example 3 | Example 4 | Example 5 | Example 6 |
|---|---|---|---|---|---|---|---|---|
| Organic resin | PPE 1 | | 70 | 70 | 70 | 70 | 70 | 70 |
| component | PPE 2 | | | | | | | |
| (parts by mass) | Curing agent | TAIC | 30 | 30 | 30 | 30 | 30 | |
| | | DVB | | | | | | 30 |
| | Reaction | PBP | 1 | 1 | 1 | 1 | 1 | 1 |
| | initiator | | | | | | | |
| | Styrene-based | Septon | | | | | | |
| | polymer | V9827 | | | | | | |
| | | SIBSTER | | | | | | |
| | | 103T | | | | | | |
| Proportion of total | (parts by | | 65 | 60 | 50 | 50 | 50 | 65 |
| organic resin | volume) | | | | | | | |
| component content | | | | | | | | |
| Inorganic filler | Boron nitride | AP-20S | 33.7 | 54.8 | 65.7 | 32.9 | 54.8 | 45.1 |
| (boron nitride) | | AP-10S | | | | | | |
| (parts by mass) | | MGP | | | | | | |
| | | SGP | 33.7 | 54.8 | 65.7 | 32.9 | 54.8 | 45.1 |
| Total Proportion of | (parts by | | 20 | 30 | 30 | 15 | 25 | 25 |
| boron nitride content | volume) | | | | | | | |
| Inorganic filler | Silica | FB-7SDC | 48.4 | 34.9 | 83.8 | 146.7 | 104.8 | 34.5 |
| (other than | | SC2300-SVJ | | | | | | |
| boron nitride) | Alumina | DAW-03AC | | | | | | |
| (parts by mass) | | | | | | | | |
| Proportion of | (parts by | | 15 | 10 | 20 | 35 | 25 | 10 |
| other inorganic | volume) | | | | | | | |
| filler content | | | | | | | | |
| CCL properties | Dk | | 3.3 | 3.4 | 3.4 | 3.3 | 3.4 | 3.4 |
| | Copper foil | | 0.60 | 0.60 | 0.50 | 0.60 | 0.50 | 0.40 |
| | peel | | | | | | | |
| | Thermal | | 1.0 | 1.2 | 1.3 | 1.0 | 1.2 | 1.4 |
| | conductivity | | | | | | | |
| Particle size | Range of | | 0.3 μm | 0.2 μm | 0.3 μm | 0.2 μm | 0.3 μm | 0.3 μm |
| distribution | 0.1-0.8 μm | | | | | | | |
| peak | Range of | | 2.9 μm | 2.9 μm | 2.9 μm | 4.4 μm | 2.9 μm | 2.9 μm |
| | 0.8-5.0 μm | | | | | | | |
| | Range of | | 8.3 μm | 8.3 μm | 8.3 μm | 8.3 μm | 8.3 μm | 8.3 μm |
| | 5.0-30.0 μm | | | | | | | |

| | | | Example 7 | Example 8 | Example 9 | Example 10 | Example 11 |
|---|---|---|---|---|---|---|---|
| Organic resin | PPE 1 | | | 60 | 60 | 80 | 80 |
| component | PPE 2 | | 70 | | | | |
| (parts by mass) | Curing agent | TAIC | 30 | 25 | 25 | 20 | 20 |
| | | DVB | | | | | |
| | Reaction | PBP | 1 | 1 | 1 | 1 | 1 |
| | initiator | | | | | | |
| | Styrene-based | Septon | | 15 | | | |
| | polymer | V9827 | | | | | |
| | | SIBSTER | | | 15 | | |
| | | 103T | | | | | |
| Proportion of total | (parts by | | 65 | 65 | 65 | 60 | 60 |
| organic resin | volume) | | | | | | |
| component content | | | | | | | |
| Inorganic filler | Boron nitride | AP-20S | 41.8 | 43.0 | 43.0 | 46.5 | 46.5 |
| (boron nitride) | | AP-10S | | | | | |
| (parts by mass) | | MGP | | | | | |
| | | SGP | 41.8 | 43.0 | 43.0 | 46.5 | 46.5 |
| Total Proportion of | (parts by | | 25 | 25 | 25 | 25 | 25 |
| boron nitride content | volume) | | | | | | |
| Inorganic filler | Silica | FB-7SDC | 31.9 | 32.9 | 32.9 | 53.4 | 35.6 |
| (other than | | SC2300-SVJ | | | | | |
| boron nitride) | Alumina | DAW-03AC | | | | | 31.7 |
| (parts by mass) | | | | | | | |
| Proportion of | (parts by | | 10 | 10 | 10 | 15 | 15 |
| other inorganic | volume) | | | | | | |
| filler content | | | | | | | |
| CCL properties | Dk | | 3.4 | 3.3 | 3.3 | 3.4 | 3.6 |
| | Copper foil | | 0.45 | 0.65 | 0.65 | 0.60 | 0.50 |
| | peel | | | | | | |
| | Thermal | | 1.4 | 1.2 | 1.2 | 1.2 | 1.2 |
| | conductivity | | | | | | |
| Particle size | Range of | | 0.3 μm | 0.3 μm | 0.3 μm | 0.3 μm | 0.3 μm |
| distribution | 0.1-0.8 μm | | | | | | |
| peak | Range of | | 2.9 μm | 2.9 μm | 2.9 μm | 2.9 gm | 2.9 μm |
| | 0.8-5.0 μm | | | | | | |
| | Range of | | 8.3 μm | 8.3 μm | 8.3 μm | 8.3 μm | 8.3 μm |
| | 5.0-30.0 μm | | | | | | |

| | | | Example 12 | Example 13 | Example 14 | Example 15 |
|---|---|---|---|---|---|---|
| Organic resin | PPE 1 | | 80 | 80 | 80 | 70 |
| component | PPE 2 | | | | | |
| (parts by mass) | Curing agent | TAIC | 20 | 20 | 20 | 30 |
| | | DVB | | | | |
| | Reaction | PBP | 1 | 1 | 1 | 1 |
| | initiator | | | | | |
| | Styrene-based | Septon | | | | |
| | polymer | V9827 | | | | |
| | | SIBSTER | | | | |
| | | 103T | | | | |
| Proportion of total | (parts by | | 55 | 55 | 55 | 70 |
| organic resin | volume) | | | | | |
| component content | | | | | | |
| Inorganic filler | Boron nitride | AP-20S | 60.9 | 60.9 | | 47.0 |
| (boron nitride) | | AP-10S | | | 60.9 | |
| (parts by mass) | | MGP | | 60.9 | | |
| | | SGP | 60.9 | | 60.9 | 47.0 |
| Total Proportion of | (parts by | | 30 | 30 | 30 | 30 |
| boron nitride content | volume) | | | | | |
| Inorganic filler | Silica | FB-7SDC | 58.3 | 58.3 | 58.3 | |
| (other than | | SC2300-SVJ | | | | |
| boron nitride) | Alumina | DAW-03AC | | | | |
| (parts by mass) | | | | | | |
| Proportion of | (parts by | | 15 | 15 | 15 | 0 |
| other inorganic | volume) | | | | | |
| filler content | | | | | | |
| CCL properties | Dk | | 3.5 | 3.5 | 3.5 | 3.4 |
| | Copper foil | | 0.50 | 0.40 | 0.50 | 0.60 |
| | peel | | | | | |
| | Thermal | | 1.3 | 1.3 | 1.2 | 1.1 |
| | conductivity | | | | | |
| Particle size | Range of | | 0.3 μm | 0.3 μm | — | 0.2 μm |
| distribution | 0.1-0.8 μm | | | | | |
| peak | Range of | | 2.9 μm | 2.9 μm | 1.0 μm | 3.6 μm |
| | 0.8-5.0 μm | | | | | |
| | Range of | | 8.3 μm | 6.7 μm | 8.3 μm | 8.3 μm |
| | 5.0-30.0 μm | | | | | |

TABLE 2

| | | | Comparative | Comparative | Comparative | Comparative | Comparative | Comparative |
|---|---|---|---|---|---|---|---|---|
| | | | Example 1 | Example 2 | Example 3 | Example 4 | Example 5 | Example 6 |
| Organic resin | PPE 1 | | 70 | 70 | 70 | 70 | 70 | 70 |
| component | PPE 2 | | | | | | | |
| (parts by mass) | Curing agent | TAIC | 30 | 30 | 30 | 30 | 30 | 30 |
| | | DVB | | | | | | |
| | Reaction | PBP | 1 | 1 | 1 | 1 | 1 | 1 |
| | initiator | | | | | | | |
| | Styrene-based | Septon V9827 | | | | | | |
| | polymer | SIBSTER 103T | | | | | | |
| Proportion of total | (parts by | | 70 | 70 | 70 | 70 | 75 | 75 |
| organic resin | volume) | | | | | | | |
| component content | | | | | | | | |
| Inorganic filler | Boron nitride | AP-20S | 93.9 | | | | 36.5 | |
| (boron nitride) | | AP-10S | | | | | 36.5 | |
| (parts by mass) | | MGP | | | | | | 36.5 |
| | | SGP | | 93.9 | | | | 36.5 |
| Total proportion of | (parts by | | 30 | 30 | 0 | 0 | 25 | 25 |
| boron nitride content | volume) | | | | | | | |
| Inorganic filler | Silica | FB-7SDC | | | 89.8 | 44.9 | | |
| (other than | | SC2300-SVJ | | | | 44.9 | | |
| boron nitride) | Alumina | DAW-03AC | | | | | | |
| (parts by mass) | | | | | | | | |
| Proportion of | (parts by | | 0 | 0 | 30 | 30 | 0 | 0 |
| other inorganic | volume) | | | | | | | |
| filler content | | | | | | | | |
| CCL properties | Dk | | 3.4 | 3.4 | 3.2 | 3.2 | 3.3 | 3.3 |
| | Copper foil | | 0.30 | 0.70 | 0.70 | 0.65 | 0.30 | 0.65 |
| | peel | | | | | | | |
| | Thermal | | 1.2 | 0.9 | 0.6 | 0.6 | 1.2 | 1.2 |
| | conductivity | | | | | | | |
| Particle size | Range of | | 0.3 μm | — | — | — | 0.2 μm | — |
| distribution | 0.1-0.8 μm | | | | | | | |
| peak | Range of | | 4.4 μm | — | — | 1.0 μm | 3.6 μm | — |
| | 0.8-5.0 μm | | | | | | | |
| | Range of | — | — | 8.3 μm | 8.3 μm | 8.3 μm | — | 8.3 μm |
| | 5.0-30.0 μm | | | | | | | |

Observations

As can be seen from Table 1, all the Examples with the use of the resin composition according to the present invention demonstrate that it is possible to obtain a cured product having low dielectric characteristics, a high thermal conductivity, and an excellent peel strength. Further, a comparison between Example 2 and Example 15 demonstrates that the thermal conductivity can be further enhanced while the peel strength is ensured by making the resin composition contain silica other than the boron nitride filler. Additionally, a comparison between Example 13 and Example 14 demonstrates that the thermal conductivity can be still further enhanced by making the resin composition contain inorganic filler such that a particle size distribution of the inorganic filler has three or more peaks in respectively specified ranges.

In contrast, as shown in Table 2, samples of Comparative Examples 1 and 5, where only boron nitrides of relatively small particle diameters are used, fail to ensure a sufficient peel strength. Additionally, samples of Comparative Examples 2 and 6 where only boron nitrides of relatively large particle diameters are used and Comparative Examples 3 and 4 where no boron nitride is used as an inorganic filler show inferior thermal conductivities.

In light of the foregoing, the following observations can be made. Samples with boron nitride of a small particle diameter only have a good thermal conductivity but a lower peel strength. Since boron nitride is poorly adherent to resin, when only boron nitride of a small particle diameter is contained, the boron nitride has a larger specific surface area, which is inferred to cause a decrease in the peel strength. Samples with boron nitride of a large particle diameter only have a good peel strength but a lower thermal conductivity. When only boron nitride of a large particle diameter is used, the boron nitride particles are more distant from one another in the resin, which is inferred to consequently lower the thermal conductivity.

As observed above, it was found that none of the samples in Comparative Examples could concurrently enhance the thermal conductivity and the peel strength.

This application is based on Japanese Patent Application No. 2020-122560 filed on Jul. 17, 2020, the contents of which are incorporated in the present application.

While the present invention is fully and appropriately described in the above by way of embodiments with reference to specific examples and drawings in order to express the present invention, it is to be recognized that those skilled in the art can readily change and/or modify the embodiments described above. Therefore, it is to be construed that the changes or modifications made by those skilled in the art are encompassed within the scope of the claims unless those changes or modifications are at a level that departs from the scope of the claims described in the claims section of the present application.

### INDUSTRIAL APPLICABILITY

The present invention has a wide range of industrial applicability in the technical field related to an electronic material and various devices using the same.

1. A resin composition, comprising:
a polyphenylene ether compound;
a curing agent reactable with the polyphenylene ether compound; and
an inorganic filler including a boron nitride filler, wherein
a particle size distribution of the inorganic filler, which is measured by a laser diffraction-based particle size distribution measuring method, has at least two peaks in a particle diameter range of 0.8 to 30.0 μm, the peaks including at least one peak in a particle diameter range of 0.8 to 5.0 μm and at least one peak in a particle diameter range of 5.0 to 30.0 μm.

2. The resin composition according to claim 1, wherein a cumulative proportion of particles in a particle diameter range of 0.1 to 5.0 μm is 20 to 80%, and a cumulative proportion of particles in a particle diameter range of 5.0 to 150.0 μm is 20 to 80% relative to a total particle size distribution of the inorganic filler as 100%.

3. The resin composition according to claim 1, wherein the polyphenylene ether compound includes a polyphenylene ether compound having at least one of groups expressed by the following formulas (1) and (2). 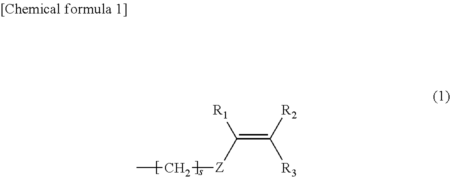
(In formula (1), s denotes an integer of 0 to 10. Z represents an arylene group. R₁ to R₃ each independently represents a hydrogen atom or an alkyl group.) 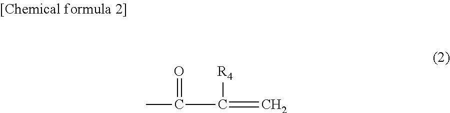
(In formula (2), R₄ represents a hydrogen atom or an alkyl group.)

4. The resin composition according to claim 1, wherein the curing agent contains at least one selected from a group consisting of:
a polyfunctional acrylate compound having two or more acryloyl groups in a molecule; a polyfunctional methacrylate compound having two or more methacryloyl groups in a molecule; a polyfunctional vinyl compound having two or more vinyl groups in a molecule; a styrene derivative; an allyl compound having an allyl group in a molecule; a maleimide compound having a maleimide group in a molecule; an acenaphthylene compound having an acenaphthylene structure in a molecule; and an isocyanurate compound having an isocyanurate group in a molecule.

5. The resin composition according to claim 1, wherein the inorganic filler further contains at least one selected from a group consisting of silica, anhydrous magnesium carbonate, alumina and silicon nitride.

6. The resin composition according to claim 5, wherein
the inorganic filler contains silica, and
a particle size distribution of the inorganic filler, which is measured by the laser diffraction-based particle size distribution measuring method, has at least three peaks in a particle diameter range of 0.1 to 30.0 μm, the peaks including at least one peak in a particle diameter range of 0.1 to 0.8 μm, at least one peak in the particle diameter range of 0.8 to 5.0 μm, and at least one peak in the particle diameter range of 5.0 to 30.0 μm.

7. The resin composition according to claim 1, wherein a content of the inorganic filler is 20 to 60 parts by volume relative to 100 parts by volume of total of the polyphenylene ether compound, the curing agent, and the inorganic filler.

8. The resin composition according to claim 7, wherein a content of boron nitride is 15 to 30 parts by volume relative to 100 parts by volume of total of the polyphenylene ether compound, the curing agent, and the inorganic filler.

9. The resin composition according to claim 7, wherein a content of an inorganic filler other than the boron nitride is 5 to 40 parts by volume relative to 100 parts by volume of the total of the polyphenylene ether compound, the curing agent, and the inorganic filler.

10. The resin composition according to claim 7, wherein a content of the boron nitride in the inorganic filler is 25 to 80 parts by volume relative to 100 parts by volume of the inorganic filler.

11. The resin composition according to claim 1, further comprising a styrene-based polymer.

12. The resin composition according to claim 1, wherein
a cured product of the resin composition has a thermal conductivity of 1.0 W/m·K or more, and a relative dielectric constant at a frequency of 10 GHz of 4.0 or less.

13. A prepreg, comprising:
the resin composition according to claim 1 or a semi-cured product of the resin composition; and
a fibrous base material.

14. A film with a resin, comprising:
a resin layer containing the resin composition according to claim 1 or a semi-cured product of the resin composition; and
a support film.

15. A metal foil with a resin, comprising:
a resin layer containing the resin composition according to claim 1 or a semi-cured product of the resin composition; and
a metal foil.

16. A metal-clad laminate, comprising:
an insulating layer containing a cured product of the resin composition according to any one of claims 1 to 12 or a cured product of the prepreg according to claim 13; and
a metal foil.

17. A wiring board, comprising:
an insulating layer containing a cured product of the resin composition according to claim 1; and wiring.

18. A metal-clad laminate, comprising:
an insulating layer containing a cured product of the prepreg according to claim 13; and
a metal foil.

19. A wiring board, comprising:
an insulating layer containing a cured product of the prepreg according to claim 13; and
wiring.
